(19) United States
(12) Patent Application Publication
(10) Pub. No.: US 2017/0045572 A1
(43) Pub. Date: Feb. 16, 2017

(54) Circuit Arrangement For Generating a Test Voltage, in Particular For Testing The Insulation of Installed Cable

(71) Applicant: Baur Prüf- und Messtechnik GMBH, Sulz (AT)

(72) Inventor: Philipp Rekers, Emsburen (DE)

(21) Appl. No.: 15/243,864

(22) Filed: Aug. 22, 2016

Related U.S. Application Data
(63) Continuation of application No. 14/379,353, filed on Aug. 18, 2014, now abandoned.

(51) Int. Cl. G01R 31/12; G01R 31/14

(52) U.S. Cl. CPC G01R 31/1272; G01R 31/14

(57) ABSTRACT

The invention relates to a circuit arrangement for generating a test voltage, in particular for testing electrical equipment, comprising an alternating voltage source or a voltage source having constant or essentially constant voltage and a circuit means connected to the voltage source for generating a preferably low-frequency alternating voltage U0. A power converter, preferably configured as a resonant converter, is connected to the alternating voltage source. A transformer device connected to the power converter is used for generating a high frequency UT, and a rectifier circuit means, in particular a cascaded and/or multistage one, is used for converting the high frequency to an amplitude that can be changed to a direct current voltage UHV. Furthermore, a switch device for charging the equipment being tested with the direct current voltage UHV and for discharging same is provided. In said circuit arrangement, the input of a converter is connected to the alternating voltage source U0 and the output of the converter is connected to the switch device for charging and discharging the equipment being tested. On the input side, the power converter is configured with (n) switch elements, and on the output side, the power converter comprises several (k) stages. The rectifier circuit means (C1 to C4, S5 to S8) is configured combined as an inverter circuit for discharging the equipment being tested, the switches of which can also be switched to valves that allow current flow in one direction only.

The invention relates to a circuit arrangement for generating a test voltage for testing electrical operating means, comprising an alternating voltage source or—alternatively—a voltage source with a constant or essentially constant voltage and with a circuit means connected thereto for generating a preferably low-frequency alternating voltage, a transformer device connected to the alternating voltage source according to one of the alternatives for generating a high voltage, rectifier circuit means, designed in particular in a cascaded and/or multi-step manner, for conversion of the high voltage into a direct voltage of variable amplitude and a circuit device for charging the test subject with the direct voltage and for discharging the test subject.

Test voltages generated with such circuit devices serve to test the insulation of electrical operating means in a general manner, but in particular to test laid power cables. The mostly capacitive test subject is charged during a period of time to both the maximum positive and negative peak test voltage.

A circuit arrangement of the type mentioned in the introduction known from DE 195 13 441 C5 is used in test generators of the so-called VLF (Very Low Frequency) type. When moving towards higher test voltages the increasingly larger volume, and also weight,—as determined by the assembly—of the high voltage vessel has a disadvantageous effect. Similarly the size also increases in the case of rectifiers and multipliers, more so in the case of the circuit device for charging and discharging the test subject, which must each be mutually insulated for the full operational voltage. Furthermore, a limit is set by component and parasitic capacitances on the cascading effect and therefore the level of the test voltage. Thus, in particular, the parts connected downstream of the cascade in the regulating element limit the cascading effect. Furthermore, the power stored in the test subject is also converted into heat. In the case of test subjects with a high capacitance or high test voltage, a troublesome cooling process is required.

WO 2009/143544 A2 discloses a VLF test generator which includes a resonant circuit with two slightly different oscillators for generating a low-frequency modulation, which generates an output voltage with a very high amplitude and very low frequency. Since the demodulator must be able to block the doubled output voltage, its structure is complex. By reason of its low weight the test generator serves in particular for transportable use in the case of insulation tests, e.g. on power cables laid in the ground.

Push-pull converters are advantageously used in the case of clocked switching regulators at power levels of over 100 W. Such switched mode mains power supplies—e.g. when designed as Royer converters—are widely used to supply VFDs (vacuum-fluorescence displays).

For higher test voltages, in accordance with the report published at the 13th European Conference and Applications (EPE2009), Barcelona, Spain 2009: “Frequency/Duty Cycle Control of LCC Resonant Converter Supplying High Voltage Very Low Frequency Test Systems” by M. Hu et al. new VLF test generators have been developed which operate with a test voltage of 0.1 Hz/85 kV (RMS). For generation of the high test voltage a full-bridge LCC resonance converter and a transformer and a Cockcroft-Walton (CW) voltage multiplier are used and the sine-wave voltage generated is then output to the cable to be tested and to a control unit for the process of discharging the test voltage, i.e. a variable resistor. The control unit is embodied in the form of a cascade of bipolar transistors (IGBTs) which are connected in parallel to a series connection of high-voltage resistors, one transistor per resistor.

The object of the invention is to create a circuit arrangement for generating a test voltage for testing electrical operating means, which takes up a comparatively small amount of space, is of low weight and is characterised by low power losses.

This object is achieved by the invention in a circuit arrangement having the features of claim 1. Advantageous developments are the subject of the subordinate claims.

A circuit arrangement for generating a test voltage for testing electrical operating means according to the invention therefore comprises an alternating voltage source or a voltage source with a constant or essentially constant voltage and with a circuit means connected to the voltage source for generating a preferably low-frequency alternating voltage U0. An inverter preferably designed as a resonant network is connected to the alternating voltage source. A transformer device connected to the inverter serves to generate a high voltage UT and a rectifier circuit means, designed in particular in a cascaded and/or multi-step manner, serves for conversion of the high voltage into a direct voltage UHV of variable amplitude. Furthermore, a circuit device for charging the test subject with the direct voltage UHV and for discharging the test subject is provided. On the input side, the inverter is designed with (n) switching elements, and on the output side the inverter comprises a plurality (k) of steps. The output of the inverter is connected to the circuit device for charging and discharging the test subject. The rectifier circuit means is designed in a combined manner as an inverter circuit for discharging the test subject, the switches of which can also be switched as valves which permit the flow of current in only one direction.

The design of the bidirectional and bipolar inverter means that the number of assemblies used in the circuit arrangement can be reduced over the described conventional structure. Instead of two high voltage transformers and two rectifier and multiplier circuits, it is possible to use only one transformer and one inverter operating in a bidirectional and bipolar manner, which has an advantageous effect on the weight of the test voltage generator. For example, a weight reduction for a test voltage generator by about 30% can be achieved.

The embodiment of the circuit arrangement in accordance with the invention preferably consists of the use of a plurality of inverters which, according to the conventional circuit structure, are advantageously capacitively coupled on the primary and secondary side as half-bridge push-pull converters.

The provision of a plurality of steps on the output side of the inverter means that the output voltage of the transformer can be reduced for the individual steps in each case to a fraction of the input voltage, which means that the switches then also only have to switch this partial voltage. This cascade design makes it possible to use higher test voltages with the circuit arrangement in accordance with the invention and the components are loaded to a lesser degree.

In the circuit arrangement in accordance with the invention there are two operating modes:
a) power is drawn from the power supply system and supplied to the test subject;
b) power is drawn from the test subject and supplied to the power supply network. As an alternative to the power supply network, another power store can be used, to which the dissipation power of the arrangement has to be supplied only during operation.

In operating mode a) a direct voltage source is used or a direct voltage is provided and generates the direct voltage in a square-wave voltage of variable frequency and—depending on the design—of variable pulse width, preferably with a very low frequency (e.g. 20 to 200 kHz). The square form is preferred but not essential. The voltage of the transformer is thus stepped, wherein in the case of a corresponding circuit structure a sine-wave current is impressed by the resonant network. In the cascade arrangement the voltage is rectified and can be varied by changing pulse width and frequency at the input, whereby the slowly varying direct voltage or slow alternating voltage (frequency less than switching frequency of half or full bridge) is generated.

In operating mode b) the high voltage at the test subject is reduced and the power stored in the form of a charged capacitance is converted into a lower voltage, supplied to the circuit arrangement in accordance with the invention and intermediately stored for the next charging process or fed into the power supply network.

This possibility of power recovery improves the degree of efficiency of the circuit arrangement in accordance with the invention over conventional circuit arrangements. Power is saved and no dissipated heat or distinctly less dissipated heat is produced. This facilitates construction and the size of the structure can be selected to be smaller.

In one embodiment of the circuit arrangement in accordance with the invention the output-side steps of the inverter are provided with an active voltage limitation, more advantageously also with an over-voltage protection.

By combining the rectifier circuit with an inverter circuit the same arrangement can be used for charging and discharging the test subject. This is an important factor in reducing size.

In order to achieve a uniform voltage division the output-side steps of the inverter are preferably symmetrical.

The output-side steps of the inverter preferably comprise a light control which is produced e.g. by means of photodiodes.

In one embodiment of the circuit arrangement in accordance with the invention a switch for one of the output-side k steps of the inverter is designed with k steps, wherein for each switch 2 k drives are provided. In other embodiments e.g. an inductive drive can be used.

The inverter is preferably designed as a resonance converter. By means of the approximately sine-wave signal progressions the components can be actuated in synchronism and pole reversal also of resulting parasitic capacitances is ensured.

One embodiment of such a resonance converter can be provided as an LLC, LCC or LCL converter which has a low dissipation power and ensures a good degree of efficiency. Advantageously, an LCC-resonant circuit is used for charging purposes and an LLC-resonant circuit is used for feedback purposes, switching between the two being effected by means of a switching element. By means of the integrated resonance converter an approximately sine-wave current can be generated and inductive reactive power to achieve zero-voltage switching, in particular of the high voltage-switches, can be provided. Otherwise, there will be a severe increase in losses and a corresponding reduction in the degree of efficiency. The voltage stress can thus be kept lower, whereby components can be designed smaller and the conduction losses are lower.

The invention will be described further hereinunder with the aid of exemplified embodiments and the drawing. This presentation serves only for explanatory purposes and is not intended to limit the invention to the specifically given feature combinations. In the figures:

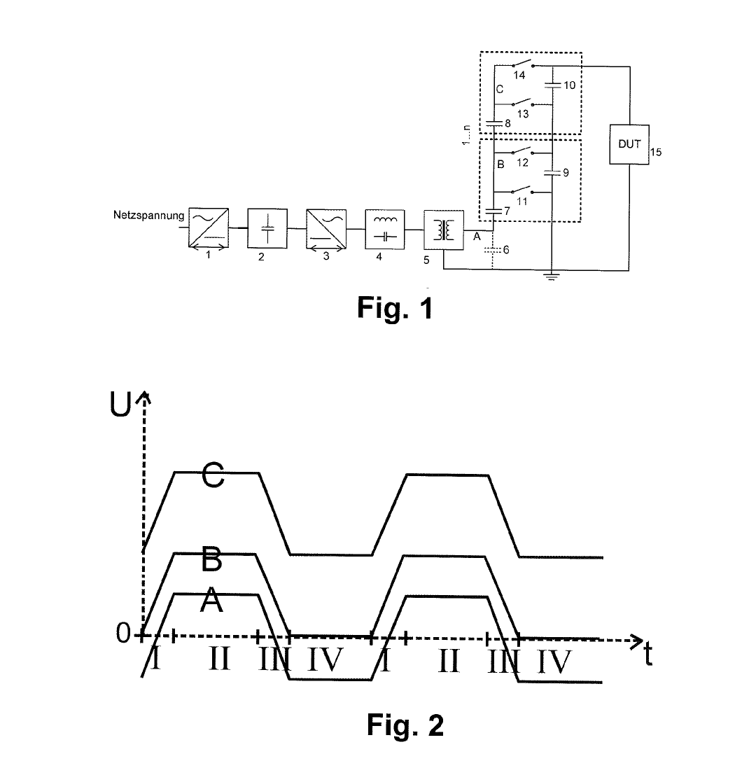

FIG. 1 shows a block circuit diagram of an exemplified embodiment of a circuit arrangement in accordance with the invention in a design as a two-step cascade converter with an integrated resonance converter;

FIG. 2 is a schematic diagram which shows the voltage progression at the points A, B and C in FIG. 1 in dependence upon time; and

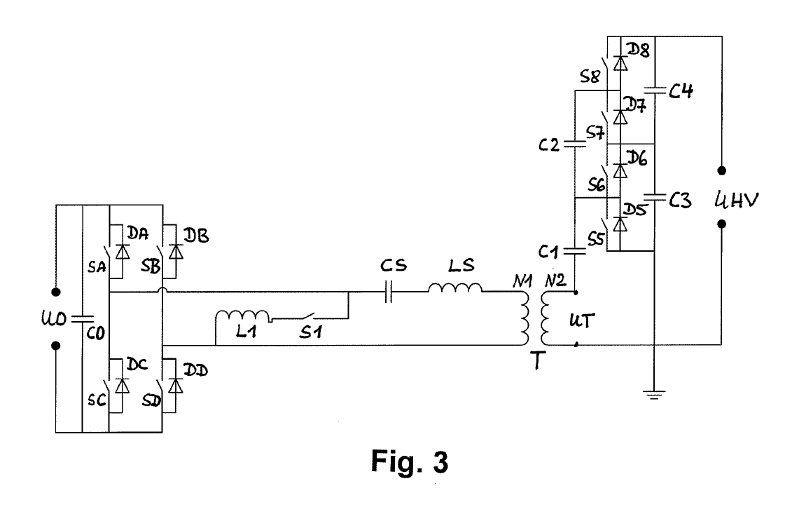

FIG. 3 shows an example of a full-bridge push-pull converter used in the circuit arrangement in accordance with the invention.

FIG. 1 shows a block circuit diagram of a circuit arrangement constructed in accordance with the invention. This includes a line rectifier 1, an intermediate circuit 2, an inverter 3, a resonant network (resonance converter) 4 and a high-voltage transformer 5. The number 6 designates an equivalent capacitance which combines the parasitic capacitances of the high voltage structure. Reference numerals 7 to 10 represent a cascade rectifier/inverter with a coupling column (capacitors 7, 8) and a smoothing column (capacitors 9, 10). High voltage switches 11 to 14 are provided. The test subject is designated with the reference 15.

The line rectifier 1 can be designed passively as a bridge rectifier, as a PFC rectifier (rectifier with power factor correction or power factor compensation PFC). When the intermediate circuit 2 is unable to completely receive the power stored in the test subject during discharge, the PFC rectifier can be bidirectional.

The intermediate circuit 2 consists of one or a plurality of capacitors which can buffer the rectified voltage from the line rectifier 1 or the rectified voltage fed back into the inverter 3. In addition to the capacitors a voltage conversion can be provided, by means of which in particular the fed-back voltage can be adjusted.

The inverter 3 can operate as an inverter in the event of a power flow to the test subject and as a rectifier in the event of power flow through feedback from the test subject. It can be designed e.g. as a half bridge or full bridge and generates a square-wave alternating voltage.

The resonant network 4 consists of an arrangement of inductive and capacitive elements which do not all have to be designed discretely. Parasitic elements of the transformer 5 and of the cascade arrangement to be described below can also be used. In the illustrated exemplified embodiment the resonant network 4 consists of a series connection of a capacitor with a coil (oscillating circuit), wherein the capacitance consists of the stray capacitance of the cascade arrangement and the coil capacitances of the transformer 5. In light of the statements above, when designing the resonant circuit 4, the capacitive power intake of the subsequent rectifier circuit and the parasitic capacitances 6 must be considered. These lead to a shift in the resonant frequency and a possible usable voltage overshoot.

The high voltage switches 11 to 14 can also be connected passively as diodes. In the illustrated exemplified embodiment, they each consist of one diode per current direction, which are each connected in series and each have a switch in parallel.

The circuit arrangement has two operating modes. In operating mode a) the line voltage is rectified in the rectifier 1 and stored in the intermediate circuit 2. The rectifier 1 smoothes the alternating voltage and provides a direct voltage. As an alternative to the embodiment of rectification with an intermediate circuit, another power store (direct voltage) can be used. An inverter is connected to the intermediate circuit 2 or an alternative power store, which inverter generates a square-wave voltage of variable frequency and—depending on the design—of variable pulse width. The resonant network 4 forms a filter for the fundamental wave of the generated square-wave voltage. The transmission behaviour can be adapted by further discrete components. The voltage at the transformer 5 and the resonant current are thus approximately sinusoidal. The resonant circuit 4 also provides reactive power and permits zero-voltage switching in the inverter 3.

In operating mode b) the high voltage at the test subject should be reduced i.e. the power flows from right to left in FIG. 1. The high voltage from the test subject 15 is divided into partial voltages in the capacitors of the smoothing column 9, 10. If the high voltage switches 11 and 13 and also 12 and 14 are actuated alternately in synchronism, a square-wave voltage is generated at the transformer. The integration of the resonant network 4 into the circuit arrangement is important. This provides reactive power in this operating mode, which reactive power makes it possible, in the time when no switch is closed, to actively switch the voltage at the transformer (see FIG. 2, intervals I, III). This significantly reduces the losses in the high voltage switches, since the parasitic capacitances of the high voltage switches and of the parasitic earth capacitances are not short-circuited. By reason of the resonant network 4 the resonant current is also approximately sinusoidal. The inverter 3 functions in this operating mode as a rectifier and supplies the power of the test subject to the intermediate circuit 2 or another power store. From the intermediate circuit 2 the power can then be supplied to the power supply network by means of a bidirectional PFC (power factor correction) rectifier.

By setting the frequency and possibly the pulse width of the output voltage of the inverter 3 the flow of power from the network to the test subject can be regulated.

FIG. 2 shows the voltage progression at the points A, B, C in FIG. 1. During the intervals II and IV the voltage is at a maximum and minimum respectively. During the intervals I and III the voltage switches through the reactive power present in the resonant circuit.

Hereinunder, an example of a resonance converter used in a circuit arrangement in accordance with the invention is described in more detail with the aid of FIG. 3.

On the primary side, a capacitor C0 is connected to a voltage source with an input voltage U0 in order to buffer it. Similarly connected to the voltage source as an inverter is a conventionally constructed full-bridge push-pull converter, having four power switches SA to SD and four diodes DA to DD, which generates a periodic square-wave voltage. A resonance converter CS, LS, N1 is connected to the inverter. Connected in parallel is a series connection of a switch S1 and an inductor L1. The voltages +U0 and −U0 with an average value of zero are alternately applied to the primary coil N1 of the transformer T. The transformer T can thus be made smaller.

A high voltage UT=N1/N2 U0 is applied to the secondary coil N2 of the transformer T in a corresponding manner. A two-step half-bridge cascade circuit C1 to C4, S5 to S8 connected thereto includes a series connection of two capacitors C1 and C2 which form a voltage splitter dividing the high voltage UT uniformly between the two steps S5, S6, C3 and S7, S8 and C4. The cascade circuit has rectifier and also filter functions and also serves as a voltage multiplier. Depending on the required level of test voltage, the cascade circuit can be designed with more steps. The magnetic coupling of the inductors is not critical in this circuit arrangement. The stray inductance of the transformer T is a component of the resonant network and therefore has no disturbing effects. The power switches and diodes only have to be designed for the magnitude of the input voltage, wherein their insulation voltage amounts to a fraction of the input voltage UHV.

In the described circuit arrangement, a square-wave current or a square-wave voltage is supplied to the transformer, wherein a positive and also a negative voltage can be converted.

In an advantageous manner, MOSFETs, IGBTs or other circuit components are used as switches. If the rectifier circuit means is replaced by the same arrangement of the primary side of the transformer T, a topology with practically identical sides is achieved. Clocking can then take place on the primary side or on the secondary side of the transformer and the power can accordingly be passed to the respective other side.

The inductivity on the primary side of the transformer can also be switched in during feedback so that the inductive reactive power for the zero-voltage switching can be provided.

FIG. 3 shows only the configuration for positive high voltage. For bipolar operation the cascade must have double the number of switches in series with differently poled diodes in each case.

1. A circuit arrangement for generating a test voltage for testing electrical operating means, comprising:
an alternating voltage source or a voltage source with a constant or essentially constant voltage (U0) and with a circuit means for generating a low-frequency alternating voltage,
an inverter connected to the alternating voltage source (U0),
a transformer device (T) connected to the cascade rectifier/inverse rectifier for generating a high voltage (UT),
a rectifier circuit means (C1 to C4, S5 to S8), designed in a cascaded and/or multi-step manner, for conversion of the high voltage (UT) into a direct voltage (UHV) of variable amplitude,
a circuit device for charging the test subject with the direct voltage (UHV) and for discharging the test subject,
characterised in that
the output of the inverter is connected to the circuit device for charging and discharging the test subject,
wherein, on the input side, the inverter is designed with (n) switching elements (SA to SD), and on the output side the inverter comprises a plurality (k) of steps, and
the rectifier circuit means (C1 to C4, S5 to S8) is designed in a combined manner as an inverter circuit for discharging the test subject (15), the switches of which can also be switched as valves which permit the flow of current in only one direction.

2. The circuit arrangement as claimed in claim 1, characterised in that the output-side steps of the inverter are provided with an active voltage limitation (R3).

3. The circuit arrangement as claimed in claim 1, characterised in that the output-side steps of the cascade rectifier/inverter are provided with an over-voltage protection.

4. The circuit arrangement as claimed in claim 1, characterised in that the output-side steps of the inverter are symmetrical.

5. The circuit arrangement as claimed in claim 1, characterised in that the output-side steps of the inverter comprise a light control.

6. The circuit arrangement as claimed in claim 1, characterised in that an inductive drive is provided for the output-side steps of the inverter.

6. The circuit arrangement as claimed in claim 1, characterised in that a switch for one of the output-side k steps of the inverter is designed with k steps in each case, wherein for each switch 2 k drives are provided.

8. The circuit arrangement as claimed in claim 11, characterised in that the resonant network comprises an LLC resonant circuit.

9. The circuit arrangement as claimed in claim 11, characterised in that the resonant network comprises an LCC resonant circuit.

10. The circuit arrangement as claimed in claim 11, wherein the resonant network comprises and LLC resonant circuit and an LCC resonant circuit, and a switch is provided for selecting the LCC or the LLC resonant circuit, wherein the LCC resonant circuit is provided for charging purposes and the LLC
resonant circuit is provided for feedback purposes.

11. The circuit arrangement as claimed in claim 1, wherein the inverter comprises a resonant network.
